(19) United States
(12) Patent Application Publication
(10) Pub. No.: US 2008/0124815 A1
(43) Pub. Date: May 29, 2008

(54) METHOD FOR POST CAP ILD/IMD REPAIR WITH UV IRRADIATION

(75) Inventors: Kelly Malone, Poughkeepsie, NY (US); Son Van Nguyen, Yorktown Heights, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/556,560

(22) Filed: Nov. 3, 2006

(51) Int. Cl. H01L 21/02; C08F 30/08; C08F 12/28; C08F 210/00

(52) U.S. Cl. 438/4; 526/279; 526/310; 526/348; 257/E21.002

(57) ABSTRACT

The present invention provides a method for repairing a damaged insulating layer in a semiconductor device comprising pre-cleaning the damaged insulating layer of the semiconductor device, depositing a CNH polymeric cap material on said damaged insulating layer, wherein said polymeric cap material comprises between about 10 and about 90 atomic percent C, between about 10 and about 70 atomic percent N, between about 10 and about 55 atomic percent H and at least one active vinyl group following deposition, depositing a further polymeric cap material on said deposited CNH polymeric cap material and treating said semiconductor device with UV irradiation to effectively repair the damaged insulating layer.

### FIELD OF THE INVENTION

The present invention relates to the field of semiconductor integrated circuit manufacturing, specifically to Back-End-Of-the-Line (BEOL) interconnected structures on ultra-large scale integrated (ULSI) circuits and related electronic structures, and is more particularly directed to a CNH dielectric cap material and a method for repairing ILD/IMD insulating layers using UV irradiation together with the CNH dielectric cap material.

### BACKGROUND OF THE INVENTION

With semiconductor technology continuing its focus on the reduction of the size of integrated circuits in order to increase circuit speed and performance, and the desire to accommodate more devices in a particular chip, the use of multi-level or multi-layer interconnects has become increasingly important. As a direct consequence, the manufacturing process of these multilevel structures has increasingly become more complex.

Following the manufacture of active devices such as capacitors, diodes, transistors and the like in what is referred to as the Front End Of the Line (FEOL) processing timeframe, the multilevel interconnects are then typically fabricated in the BEOL process. With respect to the multilevel interconnects, it is critical to insulate the metal conductors from one another. The insulating material between conductors in the same metallization level is referred to as the intermetal dielectric (“IMD”), while the insulating material between conductors in adjacent metallization levels is known as the interlayer dielectric (“ILD”).

For a long time, the insulating material used to isolate conductive lines from one another was silicon dioxide. Silicon dioxide has a dielectric constant (k) of approximately 4.0 or greater. More recently, in dealing with ILDs or IMDs, it has been generally preferred in most applications to use dielectric materials having a low dielectric constant. Low-k dielectric materials refer to those insulating materials that have a dielectric constant lower than that of silicon dioxide. With sub 90 nm technology development, ILD and IMD materials having ultra low-k (ULK) have been demanded to meet resistance-capacitance (RC) delay and performance requirements. One such category of insulating materials presently being used in BEOL processes is porous low-dielectric constant materials having a dielectric constant of 3.0 or less. Examples include porous SiLK.™ and porous silicon carbonated oxide. These insulating materials are typically deposited by plasma-enhanced chemical vapor deposition (PECVD), or may be spun on and cured by heating to remove the solvent.

While porous insulating materials have been necessary to meet BEOL RC requirements for sub 65 nm technology, these types of materials have also required special processing due to their susceptibility to damage during plasma processing or chemical exposure after their deposition. Typically, a non-sacrificial hardmask is preserved in the semiconductor structure in order to prevent damage to the porous ILD/IMD material during the cap preclean process. However, to further reduce the capacitance of the dielectric stack, there have been attempts to remove the hardmask material. This allows for the cap preclean (NH3-based) to damage the ILD/IMD by depleting the carbon through a given distance from the surface. One method to reduce the damage is to change the preclean process through various means (lower pressure, different chemistry, lower flow rate). Although these methods may reduce the amount of damage on the ILD, a damaged layer will remain nevertheless.

Accordingly, there is still a need to address the above-mentioned problems regarding the damaged porous materials.

### SUMMARY OF THE INVENTION

The present invention is directed to a method for repairing or healing a damaged insulating layer post cap deposition using UV radiation. The key to the present invention is choosing the right chemistry for the dielectric cap material (and maintaining a certain number of reactive functional groups) and UV wavelength that will allow for the insulating layer to be repaired by reacting with the cap material. By causing a reaction between the damaged insulating layer and the dielectric cap material, the present invention offers a way to achieve critical barrier properties without inducing damage to underlying low-k insulators. In particular, with the use of the dielectric cap material of the present invention in a method for repairing a damaged insulating layer, BEOL RC requirements can thus be met for 45 mm semiconductor technology and as low as 32 nm technologies.

In general terms, the present invention provides a method for repairing a damaged insulating layer in a semiconductor device that comprises:

pre-cleaning the damaged insulating layer of the semiconductor device;

depositing a CNH polymeric cap material on said damaged insulating layer, wherein said polymeric cap material comprises between about 10 and about 90 atomic percent C, between about 10 and about 70 atomic percent N, between about 10 and about 55 atomic percent H and at least one active vinyl group following deposition;

depositing a further polymeric cap material on said deposited CNH polymeric cap material; and

treating said semiconductor device with UV irradiation to effectively repair the damaged insulating layer.

The present invention is further directed to the CNH polymeric cap material used in the method of the present invention, as well as a dielectric stack comprising the deposited CNH polymeric cap material.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 is a schematic illustration of a conventional semiconductor device comprising a porous insulating layer.

FIG. 2 is a schematic illustration of the conventional semiconductor device shown in FIG. 1 after undergoing a conventional CMP process.

FIG. 3 is a schematic illustration of the semiconductor device shown in FIG. 2 after undergoing a pre-clean and having the CNH polymeric cap material in accordance with the present invention deposited thereon.

FIG. 4 is a schematic illustration of the semiconductor device shown in FIG. 3 after undergoing the further deposition of a traditional cap material and being subjected to UV irradiation.

### DETAILED DESCRIPTION OF THE PREFERRED EMBODIMENT

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

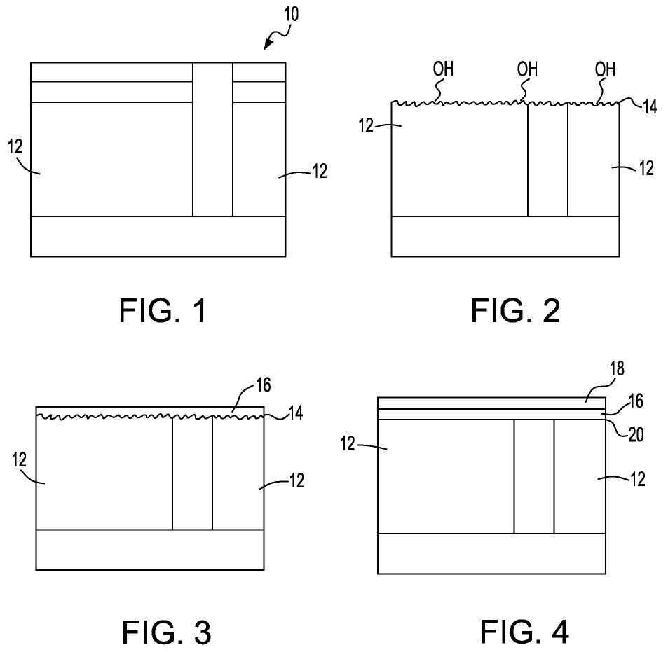

The present invention is directed to a dielectric material and its use as an intralevel or interlevel dielectric cap or hard mask/polish stop in BEOL interconnect structures. Specifically, the present invention is directed to a method for repairing a damaged insulating layer in a semiconductor device. The various stages of the semiconductor device as it is formed by the method of the present invention are illustrated in FIGS. 1 through 4 and will now be described in detail with reference thereto.

In accordance with the present invention, a conventional semiconductor structure 10 consisting of a porous insulating layer 12, as shown in FIG. 1, receives direct CMP. This is a conventional process used in the fabrication of semiconductor integrated circuits. In the method of the present invention, the porous insulating layer 12 may be either an ILD or an IMD. In FIG. 1, said porous insulating layer is identified as a porous ILD. The CMP step represents a conventional step known in the art. CMP is a very commonly used planarization technique, combining chemical surface reactions with mechanical planarization. As a result of the CMP process, the porous ILD 12 becomes damaged and —OH groups become present on the surface of the damaged porous ILD 14 as shown in FIG. 2.

The semiconductor structure 10 is then subjected to a pre-clean, followed by the deposition of the polymeric cap material 16 of the present invention. The resulting structure is illustrated in FIG. 3. The pre-clean step is also a conventionally known process. Typically, the pre-clean process effectively removes unwanted residue on the Cu surface by H atoms and other active species using a reducing H₂ plasma or an oxidizing plasma. Other common chemistries include one or more of the following gases: H₂, O₂, N₂ and NH₃.

The polymeric cap material 16 is a CNH dielectric material having a low-dielectric k. Said CNH dielectric material or film is typically deposited using either plasma enhanced chemical vapor deposition (PECVD), Ion Beam or Cathodic Arc Deposition. In addition to PECVD, high density plasma (HDP), pulsed PECVD, spin-on application, or other processes can also be used.

The CNH dielectric film of the present invention is prepared by providing at least one precursor into a Plasma Enhanced (PECVD), High Density Plasma (HDP) Chemical Vapor Deposition or Ion Beam or cathodic Arc reactor chamber to deposit a dielectric film comprising C, N, and H from said at least one precursor. At least one vinyl group is present in the precursor. Preferably two to three vinyl groups are optimal, depending on the structure of the precursor. Two to three vinyl groups are preferred as the probability of one vinyl group breaking during the deposition process is good, while the probability of breaking two vinyl groups during the deposition is much lower.

The CNH polymeric cap material 16 deposited in accordance with the present invention may be made from precursors containing C and N separated or in a ring structure. Examples of such precursors are NH₃ and hydrocarbon gases with single and double bonds such as methane, ethylene, propylene or related cyclic molecules containing one N atom and two C atoms. Candidates of preferred precursors generally include vinyl-substituted carbosilazanes (again two to three vinyl groups being optimal), polyhydridosilazanes, co-polysilazanes and alkynyl silanes.

The CNH dielectric material of the present invention comprises between about 10 and about 90, more preferably from about 30 to 60, atomic percent of C; between about 10 and about 70, more preferably from about 10 to about 40, atomic percent of N; and between about 10 and about 55, more preferably from about 20 to about 35, atomic percent of H. At least one active vinyl group remains in the deposited dielectric material.

The polymeric cap material 16 in accordance with the present invention is applied generally by a CVD process at low pressure and low RF power in order to maintain at least one active vinyl group in the deposited polymeric cap material 16.

The CNH dielectric films in accordance with the present invention have a low dielectric constant (k), with an increased resistance to water degradation of properties such as stress-corrosion cracking, Cu ingress, and other critical properties.

Following the deposition of the dielectric cap material 16, a very thin traditional cap 18 is applied to the semiconductor structure 10. The traditional or conventional cap 18 material is well-known in the art. Examples of traditional or conventional cap materials are SiN, SiC, SiCN, SiCBN, BN or CBN. Said traditional cap 18 may be applied by any conventional deposition process, such as spin-on or CVD.

In the final step of the method of the present invention, the entire semiconductor device or stack is irradiated with UV in order to initiate a reaction between the lower cap material 16 and the damaged porous ILD 14. This reaction effectively repairs the ILD surface 20 by the removal of the dangling —OH groups, and generates one less interface.

In a typical deposition process in accordance with the present invention, a substrate is placed in a 200 mm or 300 mm PECVD/HDPCVD deposition chamber, and precursors contain C and N as separated (or in a ring structure) is stabilized. The conditions used in the deposition step may include a precusor flow of 100-300 mg/m for all precursors, a He gas flow of 10-3000 sccm, and the optional use of N₂ with a flow from 10-1000 sccm said flows are stabilized to reach a reactor pressure of 1-10 Torr. The wafer chuck temperature is typically set between 100°-400° C., with 300°-400° C. range preferred. The high frequency RF power which is typically in the range from 200-1000 W is applied to a showerhead, and the low frequency RF is applied to less than 100V to enhanced ion bombardment.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method of repairing a damaged insulating layer in a semiconductor device, comprising:
pre-cleaning the damaged insulating layer of said semiconductor device;
depositing a CNH polymeric cap material on said damaged layer;
depositing a further polymeric cap material on said deposited CNH polymeric cap material; and
treating said semiconductor device with UV irradiation,
wherein said CNH polymeric cap material comprises between about 10 and about 90 atomic percent carbon, between about 10 and about 70 atomic percent nitrogen, between about 10 and about 55 atomic percent hydrogen and at least one active vinyl group.

2. The method according to claim 1, wherein the damaged insulating layer is an ILD.

3. The method according to claim 1, wherein the damaged insulating layer is an IMD.

4. The method according to claim 1, wherein said polymeric cap material comprises between about 30 to about 60 atomic percent carbon.

5. The method according to claim 1, wherein said polymeric cap material comprises between about 10 to about 40 atomic percent nitrogen.

6. The method according to claim 1, wherein said polymeric cap material comprises between about 20 to about 35 atomic percent hydrogen.

7. The method according to claim 1, wherein said depositing said CNH polymeric cap material comprises providing at least one precursor into a deposition chamber, said at least one precursor containing C and N separated or in a ring structure and at least one vinyl group.

8. The method according to claim 7, wherein said at least one precursor contains at least two vinyl groups.

9. The method according to claim 7, wherein the precursor is a vinyl-substituted carbosilazane, a polyperhydridosilazane, a co-polysilazane or an alkynyl silane.

10. The method according to claim 1, wherein said further polymeric cap material is SiN, SiC, SiCN, SiCBN, BN or CBN.

11. A CNH polymeric cap material comprising between about 10 and about 90 atomic percent carbon, between about 10 and about 70 atomic percent nitrogen, between about 10 and about 55 atomic percent hydrogen and at least one active vinyl group.

12. The CNH polymeric cap material according to claim 11, wherein said polymeric cap material comprises between about 30 to about 60 atomic percent carbon.

13. The CNH polymeric cap material according to claim 11, wherein said polymeric cap material comprises between about 10 to about 40 atomic percent nitrogen.

14. The CNH polymeric cap material according to claim 11, wherein said polymeric cap material comprises between about 20 to about 35 atomic percent hydrogen.

15. A semiconductor device comprising a CNH polymeric cap material comprising between about 10 and about 90 atomic percent carbon, between about 10 and about 70 atomic percent nitrogen, between about 10 and about 55 atomic percent hydrogen and at least one active vinyl group.
